(19) United States
(12) Patent Application Publication
(10) Pub. No.: US 2026/0149236 A1
(43) Pub. Date: May 28, 2026

(54) LASER DIODE DRIVING CIRCUIT AND LASER DIODE DRIVING METHOD

(71) Applicant: NEC Corporation, Tokyo (JP)

(72) Inventors: Seigo TAKAHASHI, Tokyo (JP); Hiroki KAWAHARA, Tokyo (JP)

(73) Assignee: NEC Corporation, Tokyo (JP)

(21) Appl. No.: 19/398,326

(22) Filed: Nov. 24, 2025

(30) Foreign Application Priority Data
Nov. 28, 2024 (JP) 2024-207249

(51) Int. Cl. H01S 5/042; H01S 5/0683

(52) U.S. Cl. CPC H01S 5/0428; H01S 5/06835

(57) ABSTRACT

There is provided a laser diode driving circuit including a pulse-modulated bias applying circuit that applies a pulse-modulated bias to a laser diode to bring the laser diode in pulse oscillation, a reverse bias current applying circuit that applies a reverse bias to the laser diode to make a gain of the laser diode temporarily negative during the pulse oscillation, and a clock source that synchronizes the pulse-modulated bias and the reverse bias.

### INCORPORATION BY REFERENCE

This application is based upon and claims the benefit of priority from Japanese patent application No. 2024-207249, filed on Nov. 28, 2024, the disclosure of which is incorporated herein in its entirety by reference.

### TECHNICAL FIELD

The present disclosure relates to a laser diode driving circuit and a laser diode driving method.

### BACKGROUND ART

JP 2000-183448 A discloses that a reverse bias is applied in a case where a laser diode is turned on or off in accordance with an input pulse signal.

### SUMMARY

However, such application of a reverse bias is insufficient to stabilize the pulse intensity of laser light to reduce jitter. Thus, an example object of the present disclosure is to provide a laser diode driving circuit that stabilizes the pulse intensity of laser light to reduce jitter.

A laser diode driving circuit according to a first example aspect of the present disclosure includes
a pulse-modulated bias applying circuit that applies a pulse-modulated bias to a laser diode to bring the laser diode in pulse oscillation,
a reverse bias current applying circuit that applies a reverse bias to the laser diode to make a gain of the laser diode temporarily negative during the pulse oscillation, and
a clock source that synchronizes the pulse-modulated bias and the reverse bias.

A laser diode driving method according to a second example aspect of the present disclosure includes
applying a pulse-modulated bias to a laser diode to bring the laser diode in pulse oscillation,
applying a reverse bias to the laser diode to make a gain of the laser diode temporarily negative during the pulse oscillation, and
synchronizing the pulse-modulated bias and the reverse bias.

According to the present disclosure, an example advantage is that a laser diode driving circuit stabilizes the pulse intensity of laser light to reduce jitter.

### BRIEF DESCRIPTION OF DRAWINGS

The above and other aspects, features and advantages of the present disclosure will become more apparent from the following description of certain exemplary embodiments when taken in conjunction with the accompanying drawings, in which:

FIG. 1 is a block diagram illustrating configurations for a laser diode driving circuit according to the present disclosure;

FIG. 2 illustrates a related laser diode driving method;

FIG. 3 illustrates examples of a bias applied to a laser diode according to the present disclosure;

FIG. 4 illustrates a related example of a bias applied to a laser diode;

FIG. 5 illustrates examples of a merger in the laser diode driving circuit according to the present disclosure;

FIG. 6 illustrates multiplexing of a pulse-modulated bias and a sinusoidal bias that are different in frequency according to the present disclosure;

FIG. 7 illustrates the multiplexing of the pulse-modulated bias and the sinusoidal bias according to the present disclosure;

FIG. 8 illustrates a case where a frequency selective filter is used as the merger in the laser diode driving circuit according to the present disclosure;

FIG. 9 illustrates a case where the frequency selective filter multiplexes a pulse-modulated bias and a sinusoidal bias that are different in frequency according to the present disclosure;

FIG. 10 illustrates a pulse laser oscillated by the laser diode driving circuit according to the present disclosure;

FIG. 11 illustrates pulse lasers oscillated by a related laser diode driving circuit, the pulse lasers being different in applied current;

FIG. 12 is a block diagram illustrating a modified configuration of the laser diode driving circuit according to the present disclosure; and

FIG. 13 illustrates a pulse laser oscillated by the laser diode driving circuit according to the present disclosure.

### EXAMPLE EMBODIMENT

### Description of Related Pulse Light Source using Laser Diode

There is a circuit for a laser diode (LD) light source necessary for achievement of a pulse light source capable of operating on a 2.5-GHz clock and having stability and no correlation. In a BB84 QKD system, a pulse light source synchronized with a system clock is required for transmission (Alice).

Here, optical pulses at regular intervals output from such a pulse light source are intended to fulfill the following three items, simultaneously.
(1) Short pulses in the direction of time
(2) Stable pulse intensity with less jitter
(3) No correlation between adjacent pulses

A short-pulse light source using a low-cost semiconductor LD has been developed since the beginning of LD development for optical fiber communications, and the following two techniques have been mainly adopted.
Short pulse generation due to relaxation oscillation
Pulse shaping due to bias application
Takao Furuse, “Electrical Treatment of Laser Diode”, Optics 13(2), p.p. 118 (1984.4)
Kazuhisa Uomi, The Institute of Electronics, Information and Communication Engineers, “Knowledge base”, 2-5-3 Relaxation Oscillation Frequency and Modulation Band

Tetsuhiko Ikegami, “Direct Modulation of Semiconductor Lasers”, OYO BUTURI, 47(9), p.p. 812 (1978)
Moustafa F Ahmed, “Influence of transmission bit rate on performance of optical fibre communication systems with direct modulation of laser diodes,” J. Phys. D: Appl. Phys. 42(2009)185104(8pp)
Mark Donhowe, “Specifying Optical Modulation Amplitude instead of Extinction Ratio,” IEEE 802.3 Higher Speed Study Group, September 1999

For such techniques, an optical technique or an element structure technique has been studied. However, electrically, only bias current is adjusted in such a way that short pulsing is achieved due to reduced current and shaping is achieved due to increased current. As a result, short pulsing and pulse shaping for stabilization of pulse oscillation have conflicting effects. The bias application causes a strong correlation to the correlation and thus is unacceptable.

Decorrelation between pulses has been studied in the development of a quantum physical random number source, and the relationship between bias and correlation has been revealed.

Roman Shakhovoy et al., “Influence of chirp, Jitter and Relaxation Oscillations on Probabilistic Properties of Laser Pulse Interference”, IEEE J. of Q. Elec., Vol. 57(2), April 2021

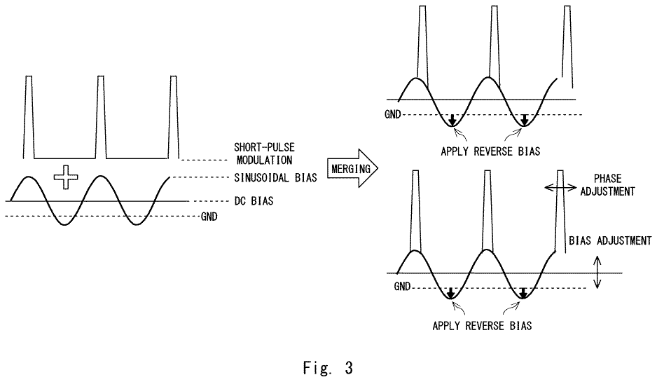

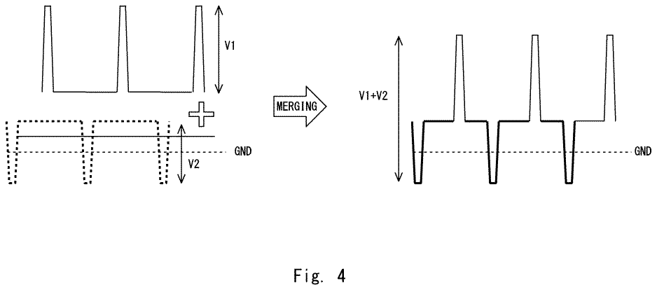

Also, according to the above example of literature, control of correlation depends on adjustment of bias current. Referring to FIGS. 3 and 4, due to adjustment of slight current between 8 mA and 9 mA, a distribution profile varies remarkably.

A change of 1 mA to a LD modulation current of approximately 50 mA is small as an allowable range, and thus changes in LD efficiency and circuit due to a change in ambient temperature and LD time-dependent deterioration are difficult to allow.

In order to cope with such changes in LD efficiency and circuit due to a change in ambient temperature and LD time-dependent deterioration, an evaluation circuit as a monitor mechanism for the state of correlation using an interferometer is required as a new addition, but leads to an increase in cost and an increase in size and thus is unfavorable.

### Description of Laser Diode Driving Circuit and Laser Diode Driving Method according to Example Embodiment

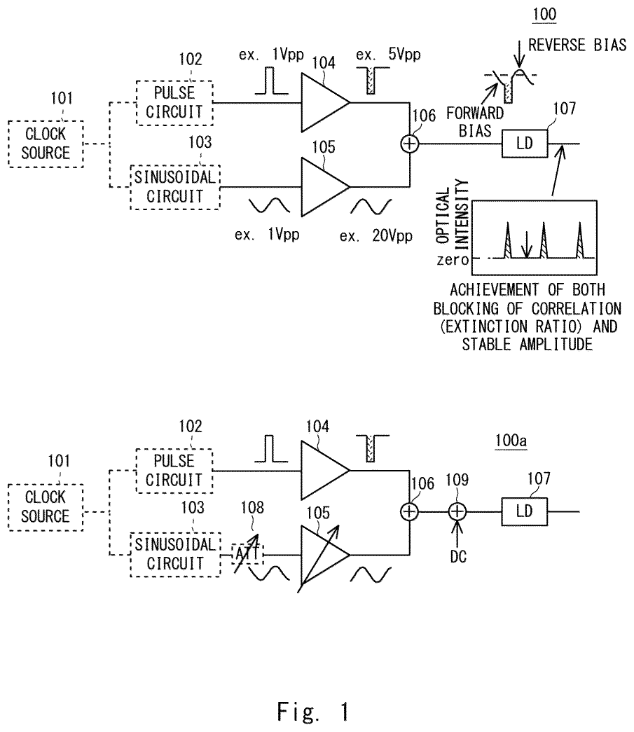

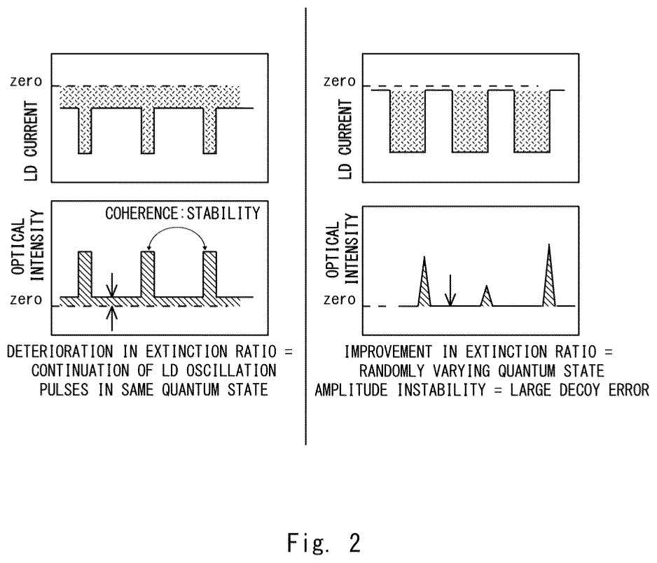

FIG. 1 is a block diagram illustrating configurations for a laser diode driving circuit according to the present disclosure. FIG. 2 illustrates a related laser diode driving method. FIG. 3 illustrates examples of a bias applied to a laser diode according to the present disclosure. FIG. 4 illustrates a related example of a bias applied to a laser diode. A laser diode driving circuit and a laser diode driving method according to an example embodiment will be described with reference to FIGS. 1 to 4. Note that, herein, such a bias is biased.

As illustrated in the upper part of FIG. 1, a laser diode driving circuit 100 according to an example embodiment includes a clock source 101, a pulse circuit 102, a sinusoidal circuit 103, an inverting amplifier circuit 1(104), an inverting amplifier circuit 2(105), a merger 106, and a laser diode 107.

The clock source 101 is connected to the pulse circuit 102 and the sinusoidal circuit 103. The clock source 101 synchronizes the clock frequency of the pulse circuit 102 and the clock frequency of the sinusoidal circuit 103 to facilitate laser oscillation.

The pulse circuit 102 serves as a part of a pulse-modulated bias applying circuit that applies a pulse-modulated bias to the laser diode 107 to bring the laser diode 107 in pulse oscillation. The pulse circuit 102 oscillates pulse voltage, for example, at 1 Vpp (peak to peak).

The inverting amplifier circuit 1(104) is connected to the pulse circuit 102. The inverting amplifier circuit 1(104) amplifies, for example, a pulse voltage of 1 Vpp to 5 Vpp and inverts the polarity of the pulse voltage. Here, a forward bias to the laser diode 107 is defined as downward.

The sinusoidal circuit 103 serves as a part of a reverse bias current applying circuit that applies a reverse bias to the laser diode 107 to make the gain of the laser diode 107 temporarily negative during pulse oscillation. In more detail, the sinusoidal circuit 103 serves as a sinusoidal generation circuit that generates a sinusoidal bias for generation of a reverse bias. The sinusoidal circuit 103 generates, for example, sinusoidal voltage at 1 Vpp.

The inverting amplifier circuit 2(105) is connected to the sinusoidal circuit 103. The inverting amplifier circuit 2(105) amplifies, for example, a sinusoidal voltage of 1 Vpp to 20 Vpp and inverts the polarity of the sinusoidal voltage.

The merger 106 merges a pulse-modulated bias and a sinusoidal bias. The bias resulting from the merging is applied to the laser diode 107. The laser diode 107 oscillates pulsed light. A forward bias and a reverse bias are alternately applied to the laser diode 107 in a sinusoidal manner, and a short-pulse modulation signal is superimposed thereon. Thus, the laser diode 107 achieves stable short-pulse oscillation.

As illustrated in the lower part of FIG. 1, for achievement of the present disclosure, a laser diode driving circuit 100a may be provided as a configuration. The laser diode driving circuit 100a includes an attenuator (ATT) 108 and a merger 109 that multiplexes direct-current voltage, in addition to a configuration identical to the configuration of the laser diode driving circuit 100.

The attenuator 108 and an inverting amplifier circuit 2(105) are each capable of adjusting a sinusoidal amplitude. The attenuator 108 and the inverting amplifier circuit 2(105), which serve as sinusoidal adjusters, are relatively inexpensive and thus are preferable for the laser diode driving circuit 100a.

The merger 109 serves as a merger for applying a constant voltage. A direct-current bias generation circuit connected to the merger 109 generates a direct-current bias to be applied for bias adjustment. The direct-current bias generation circuit applies a constant voltage to the laser diode driving circuit 100a through the merger 109, thereby performing adjustment in such a way that a laser diode 107 achieves pulse oscillation easily with a region in which the laser diode 107 has a negative gain due to inversion.

As illustrated in the left part of FIG. 2, according to the related laser diode driving method, only the level of bias is adjusted. Thus, in a case where stable short pulses are obtained with a high bias, stimulated emission continues in quenching parts, leading to a high correlation between pulses. That is, due to a deterioration in extinction ratio and the continuation of LD oscillation, the pulses have the same quantum state.

As illustrated in the right part of FIG. 2, shallowing the level of bias causes remarkable relaxation oscillation, and thus a constant amplitude is difficult to keep between short pulses. That is, in spite of an improved extinction ratio and a randomly varying quantum state, an unstable amplitude causes a large decoy error.

As illustrated in FIG. 3, a short-pulse modulation signal, a sinusoidal bias, and a direct-current (DC) bias are combined together. Although the polarity in FIG. 3 is opposite to that in FIG. 1, the upper side and lower side are indicated as the positive and negative, respectively, for easy understanding.

As Point 1, the pulse modulation signal is applied at each positive peak of the sinusoidal bias or just after each positive peak. After application of the positive sinusoidal bias, the pulse modulation signal is applied with plenty of carriers accumulated, leading to efficient laser oscillation. The positive sinusoidal amplitude is equal to or more than 50% of the oscillation threshold of the laser diode 107 in only sinusoidal modulation. This condition is also for efficient laser oscillation.

As Point 2, bias adjustment is performed by the direct-current bias, facilitating laser oscillation. Note that the direct-current bias is applied at each negative peak of the sinusoidal bias in such a way that the laser diode 107 has a negative gain. That is, the magnitude of the direct-current bias is smaller than half of the amplitude of the sinusoidal bias.

In order for the laser diode 107 to obtain a negative gain, obtaining such a combined waveform as illustrated in FIG. 4 is conceivable. However, for generation of a reverse bias state using such a waveform as indicated with a dashed line, a wide-band and high-output amplifier is required, and thus such generation is difficult to achieve or is high in cost.

This is because the pulse modulation signal and reverse bias pulses occupy the same frequency band and an amplifier is required to have a double output amplitude. Short pulses having approximately 5 Vpp are required for modulation of the laser diode 107. Periodically generating a pulse signal having 5 Vpp and a pulse width of 50 psec at 2.5 GHz results in a high-cost configuration.

However, as of 2024, a microwave IC used in a sinusoidal bias generation circuit costs a few hundred yen, and thus a reduction can be made in cost.

Due to the above-described configuration, provided is a laser diode driving circuit that stabilizes the pulse intensity of laser light to reduce jitter. In addition, optical pulses generated by the laser diode driving circuit according to the present disclosure correspond to short pulses in the direction of time. Furthermore, the optical pulses generated by the laser diode driving circuit according to the present disclosure have no correlation between adjacent pulses.

### Description of Mergers According to Example Embodiments

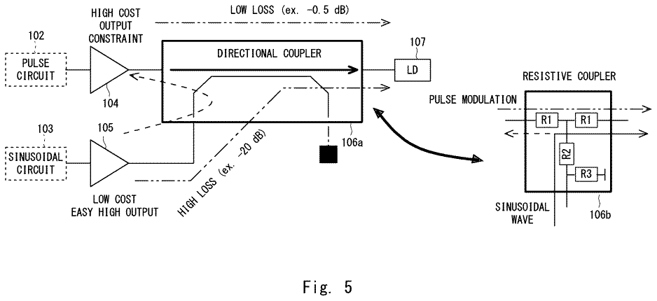

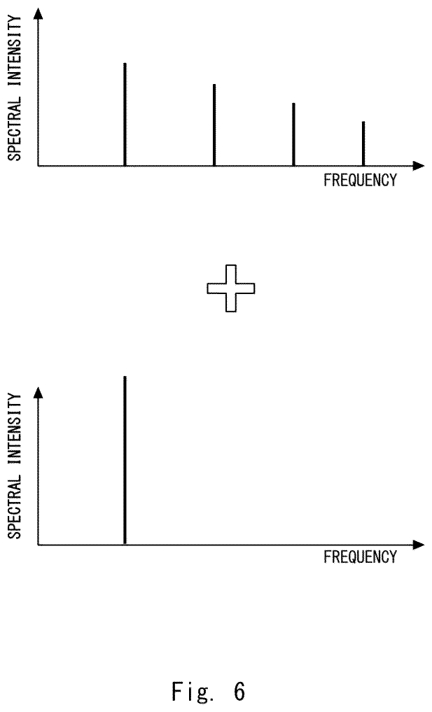

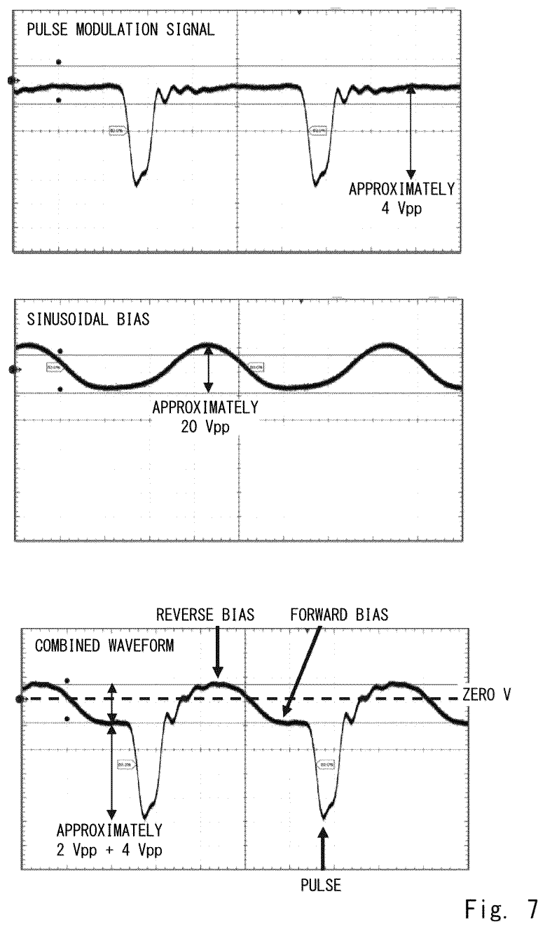

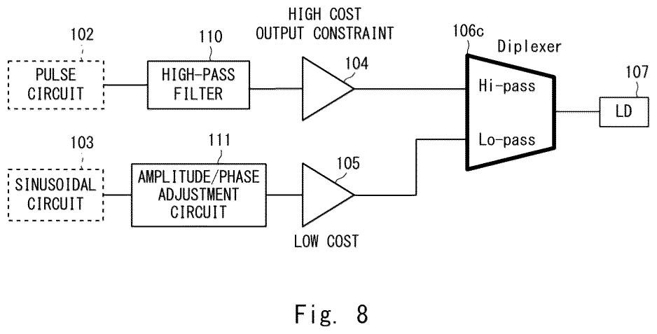

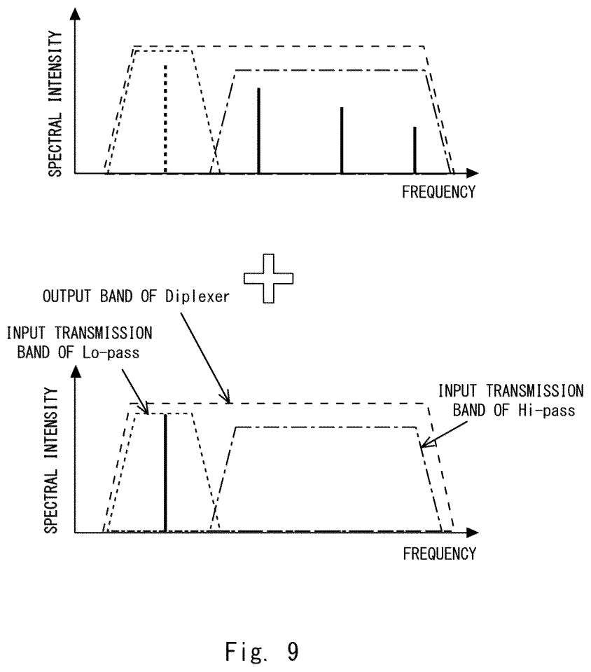

FIG. 5 illustrates examples of a merger in the laser diode driving circuit according to the present disclosure. FIG. 6 illustrates multiplexing of a pulse-modulated bias and a sinusoidal bias that are different in frequency according to the present disclosure. FIG. 7 illustrates the multiplexing of the pulse-modulated bias and the sinusoidal bias according to the present disclosure. FIG. 8 illustrates a case where a frequency selective filter is used as the merger in the laser diode driving circuit according to the present disclosure. FIG. 9 illustrates a case where the frequency selective filter multiplexes a pulse-modulated bias and a sinusoidal bias that are different in frequency according to the present disclosure. Mergers according to example embodiments will be described with reference to FIGS. 5 to 9.

A merger 106 according to an example embodiment serves, for example, as a merger that makes the degree of coupling of a pulse modulated bias and the degree of coupling of a sinusoidal bias different from each other. As illustrated in the left part of FIG. 5, as the merger 106 for a pulse circuit 102 and a sinusoidal circuit 103, a directional coupler 106a is used. The lower part of FIG. 6 illustrates a sinusoidal bias generated by the sinusoidal circuit 103. As illustrated in the lower part of FIG. 6, the sinusoidal bias includes only a fundamental wave. Thus, high output is obtained at low cost. Use of such a sinusoidal bias enables application of a low-cost and high-output inverting amplifier circuit 2(105). Thus, the necessity of considering loss at the time of merging of a sinusoidal wave is alleviated. The sinusoidal bias passes through a route that causes a large loss, such as a loss of −20 dB.

The upper part of FIG. 6 illustrates a pulse modulation signal oscillated by the pulse circuit 102. As illustrated in the upper part of FIG. 6, the pulse modulation signal includes a plurality of frequency bands. Thus, high output is difficult to achieve. An inverting amplifier circuit 1(104) for a pulse-modulated bias is high in cost and has output limitation. Thus, the loss of a merging route for the pulse-modulated bias is required to be reduced as much as possible. A sharp pulse modulation signal generated by the inverting amplifier circuit 1(104) is applied to a laser diode 107, without any attenuation and waveform deterioration, for pulse modulation. The pulse-modulated bias passes through a route that causes a low loss, such as a loss of −0.5 dB.

As illustrated in the right part of FIG. 5, as a merger for the pulse circuit 102 and the sinusoidal circuit 103, a resistive coupler 106b may be used. Note that the sinusoidal bias is likely to be applied to the inverting amplifier circuit 1(104). Entry of the sinusoidal bias into the inverting amplifier circuit 1(104) causes a deterioration in the waveform of the pulse modulation signal. The directional coupler 106a has a small route for reflection from the sinusoidal circuit 103 to the pulse circuit 102. Thus, the directional coupler 106a is suitable as a merger according to an example embodiment.

The upper part of FIG. 7 illustrates a pulse modulation signal having 4 Vpp output from the inverting amplifier circuit 1(104). The middle part of FIG. 7 illustrates a sinusoidal bias having 20 Vpp output from the inverting amplifier circuit 2(105). The directional coupler 106a merges the pulse modulation signal and the sinusoidal bias, thereby generating a combined waveform of the pulse modulation signal having 4 Vpp and the sinusoidal bias having 2 Vpp and a loss of −20 dB as illustrated in the lower part of FIG. 7.

As illustrated in FIG. 8, as a merger 106 for a pulse circuit 102 and a sinusoidal circuit 103, a frequency selective filter (diplexer) 106c may be used. The upper part of FIG. 9 illustrates a pulse modulation signal. The lower part of FIG. 9 illustrates a sinusoidal bias. The frequency of the fundamental wave of the pulse modulation signal and the frequency of the sinusoidal bias are identical, and thus a high-pass filter removes the fundamental wave from the pulse modulation signal and then the frequency selective filter 106c merges the pulse modulation signal and the sinusoidal bias. That is, the pulse modulation signal is input to Hi-pass, so that harmonics are transmitted. The sinusoidal bias is input to Lo-pass and then is transmitted. A sinusoidal amplifier that enables high output and is low in cost covers a fundamental component. The frequency selective filter 106c selects the sinusoidal bias as the fundamental wave and selects a pulse modulated bias as the harmonics.

The fundamental wave is removed from an amplified signal of the pulse modulation signal difficult to bring into high output in a wide band, enabling increased signal output on the higher-frequency side with inhibition of power dispersion.

Use of the frequency selective filter 106c enables a reduction in loss in comparison to the directional coupler 106a. Only a harmonic component is left in the pulse modulation signal due to removal of the fundamental component, so that the inverting amplifier circuit 1(104) has a narrower bandwidth and power is concentrated on the high-frequency side in the case of the same output, enabling a large amplitude.

As illustrated in FIG. 8, for use of the frequency selective filter 106c, a high-pass filter 110 and an amplitude/phase adjustment circuit 111 are added. A phase adjustment circuit that controls the phase relationship between the pulse modulated bias and the sinusoidal bias is required even in a case where no frequency selective filter 106c is provided. Thus, additional constituents are the high-pass filter 110 and an amplitude adjustment circuit. The amplitude adjustment circuit is added because the sinusoidal amplitude after merging is likely to be affected.

### Description of Evaluation Results of Laser Diode Driving Circuit According to Example Embodiment

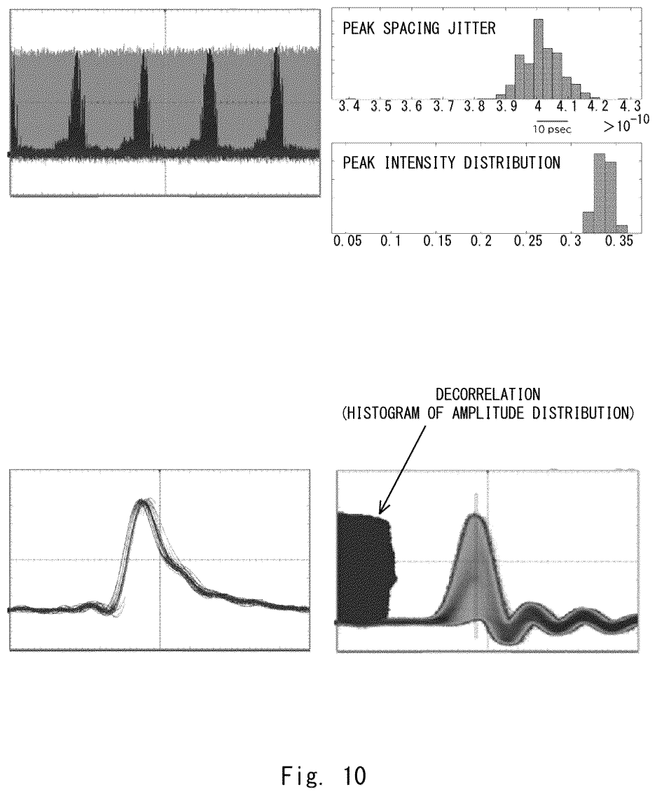

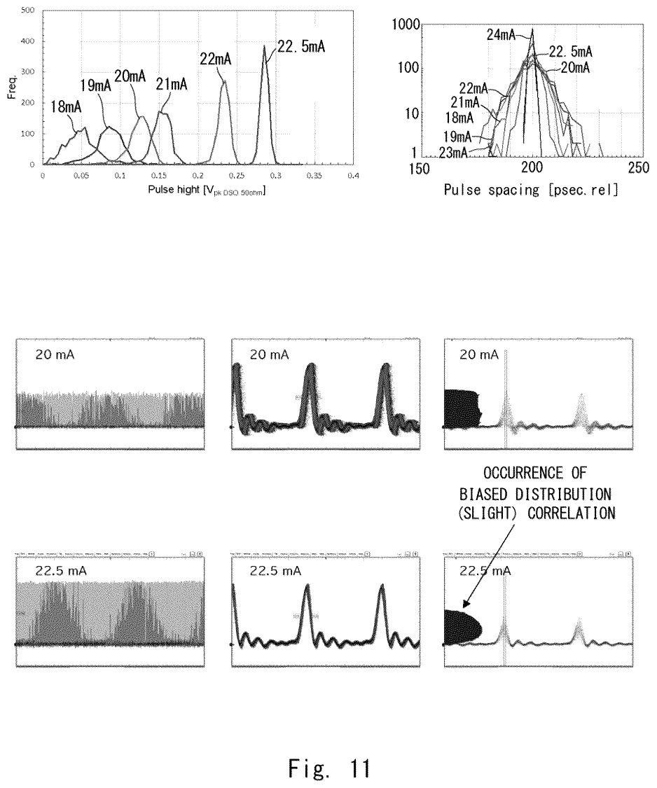

FIG. 10 illustrates a pulse laser oscillated by the laser diode driving circuit according to the present disclosure. FIG. 11 illustrates pulse lasers oscillated by a related laser diode driving circuit, the pulse lasers being different in applied current. Evaluation results of a laser diode driving circuit according to an example embodiment will be described with reference to FIGS. 10 and 11.

The upper left part of FIG. 10 illustrates an overlook of a pulse train. Because of an almost constant pulse intensity, there is no remarkably uneven upper edge.

The upper right part of FIG. 10 indicates analysis results of peak points in the upper left part of FIG. 10. The upper section of the upper right part indicates jitter regarding the spacing between pulses, and a standard deviation of approximately 7 psec, which is sufficiently small, is obtained. The lower section of the upper right part indicates a peak intensity distribution, and very stable pulses are obtained because of a distribution of approximately ±10% or less.

The lower left part of FIG. 10 illustrates an enlarged waveform including pulses superimposed, the pulses each corresponding to a single pulse. A full width at half maximum of approximately 60 psec is obtained.

The lower right part of FIG. 10 indicates an evaluation result of inter-pulse correlation using a delay interferometer. A histogram indicated on the left side of the lower right part indicates a correlation distribution. The histogram is distributed over the entire amplitude, and thus it can be found that the correlation is sufficiently spread.

The method of measuring the correlation between pulses is based on the following: Toshiya Kobayashi et al., “Evaluation of the phase randomness of the light source in quantum key distribution systems with an attenuated laser,” Phys. Rev. A90,032320(Spt. 2014).

The related laser diode driving circuit will be described with reference to FIG. 11.

The upper section of FIG. 11 indicates an intensity distribution and a pulse spacing distribution regarding a pulse output from a laser diode as a function of bias current. Along with an increase in bias current, the intensity distribution narrows and additionally jitter reduces.

The middle section of FIG. 11 indicates a waveform with a weak bias current (20 mA). According to an overlook of pulses in the left part of the middle section, variations occur in amplitude. Referring to the middle part of the middle section, jitter is observed. In a coherent waveform in the right part of the middle section, a histogram is widely distributed.

The lower section of FIG. 11 indicates a waveform with a large bias current (22.5 mA). Referring to the left part of the lower section, a constant intensity is obtained with fewer variations in amplitude. Referring to the middle part of the lower section, the waveform has less jitter. However, in a coherent waveform in the right part of the lower section, the distribution of a histogram narrows centrally and correlation occurs.

In the related laser diode driving circuit, a state where stable pulse intensity and correlation are both achieved is intermediate between 20 mA and 22.5 mA. The state has a small allowable range and is sensitive to influence of ambient temperature and time-dependent deterioration, so that adjustment therefor is difficult. For stabilization control, amplitude distribution observation using an interferometer and a wide-band optical detector is required, leading to an unfavorable configuration, such as a high-cost configuration or a large-size configuration.

### Description of Laser Diode Driving Circuit According to Another Example Embodiment

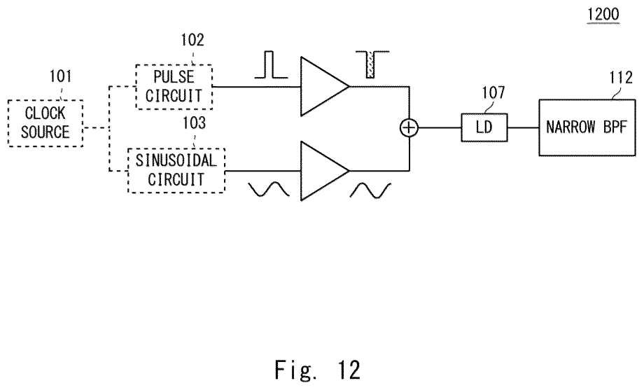

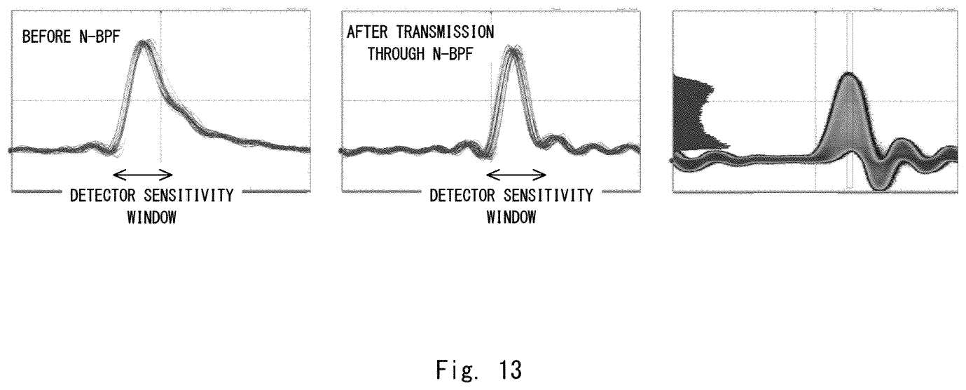

FIG. 12 is a block diagram illustrating a modified configuration of the laser diode driving circuit according to the present disclosure. FIG. 13 illustrates a pulse laser oscillated by the laser diode driving circuit according to the present disclosure. A laser diode driving circuit according to another example embodiment will be described with reference to FIGS. 12 and 13.

As illustrated in FIG. 12, a laser diode driving circuit 1200 according to another example embodiment is different from the laser diode driving circuit 100 according to an example embodiment in that a narrow band pass filter (N-BPF) 112 is further provided.

The narrow band pass filter 112 is added on the output side of a laser diode 107. The narrow band pass filter 112 narrows a pulse waveform output from the laser diode 107. Passage of an output from the laser diode 107 through the narrow band pass filter 112 enables accurate management of “a single photon state in Alice's output unit” required in a QKD system.

As illustrated in the left part of FIG. 13, before addition of the N-BPF 112, a pulse width does not fall within a detector sensitivity window. However, as illustrated in the middle part of FIG. 13, due to addition of the N-BPF 112, the pulse width falls within the detector sensitivity window. In addition, as illustrated in the right part of FIG. 13, an M-shaped histogram is obtained and an effect of causing correlation to disappear is obtained.

As a QKD unique phenomenon, only photons that enter the sensitivity window of Bob's photon detector perform key generation, and thus the energy of the tail of the pulse out of the window is not necessarily detected. Alice's photon number management is controlled by monitoring the average optical intensity, and thus the intensity of the pulse in the window attenuates. Then, a reduction is made in the photon detection rate at Bob, causing a reduced key generation rate in the system. The N-BPF 112 performs shaping on the pulse waveform, so that an improvement can be expected in key generation efficiency.

While the present disclosure has been particularly shown and described with reference to example embodiments thereof, the present disclosure is not limited to these example embodiments. It will be understood by those of ordinary skill in the art that various changes in form and details may be made therein without departing from the spirit and scope of the present disclosure as defined by the claims. And each embodiment can be appropriately combined with at least one of embodiments.

Each of the drawings or figures is merely an example to illustrate one or more example embodiments. Each figure may not be associated with only one particular example embodiment, but may be associated with one or more other example embodiments. As those of ordinary skill in the art will understand, various features or steps described with reference to any one of the figures can be combined with features or steps illustrated in one or more other figures, for example to produce example embodiments that are not explicitly illustrated or described. Not all of the features or steps illustrated in any one of the figures to describe an example embodiment are necessarily essential, and some features or steps may be omitted. The order of the steps described in any of the figures may be changed as appropriate.

Some or all of the above example embodiments may also be described as the following Supplementary Notes, but are not limited to the following.

### Supplementary Note 1

A laser diode driving circuit including:
a pulse-modulated bias applying circuit configured to apply a pulse-modulated bias to a laser diode to bring the laser diode in pulse oscillation;
a reverse bias current applying circuit configured to apply a reverse bias to the laser diode to make a gain of the laser diode temporarily negative during the pulse oscillation; and
a clock source configured to synchronize the pulse-modulated bias and the reverse bias.

### Supplementary Note 2

The laser diode driving circuit according to Supplementary Note 1, further including a sinusoidal generation circuit configured to generate a sinusoidal bias for generation of the reverse bias.

### Supplementary Note 3

The laser diode driving circuit according to Supplementary Note 2, further including a direct-current bias generation circuit configured to generate a direct-current bias to be applied for adjustment of the sinusoidal bias.

### Supplementary Note 4

The laser diode driving circuit according to Supplementary Note 3, wherein a positive amplitude of the sinusoidal bias is equal to or more than 50% of an oscillation threshold of the laser diode in only sinusoidal modulation.

### Supplementary Note 5

The laser diode driving circuit according to Supplementary Note 2, further including a merger configured to merge the pulse-modulated bias and the sinusoidal bias, the merger being configured to make a degree of coupling of the pulse-modulated bias and a degree of coupling of the sinusoidal bias different from each other.

### Supplementary Note 6

The laser diode driving circuit according to Supplementary Note 5, wherein the merger includes a directional coupler or a resistive coupler.

### Supplementary Note 7

The laser diode driving circuit according to Supplementary Note 2, further including a frequency selective filter configured to merge the pulse-modulated bias and the sinusoidal bias, the frequency selective filter being configured to select the sinusoidal bias as a fundamental wave and select the pulse-modulated bias as a harmonic.

### Supplementary Note 8

The laser diode driving circuit according to Supplementary Note 2, further including a phase adjustment circuit configured to control a phase relationship between the pulse-modulated bias and the sinusoidal bias.

### Supplementary Note 9

The laser diode driving circuit according to Supplementary Note 2, further including a narrow band pass filter configured to narrow a pulse waveform, the narrow band pass filter being configured to allow an output from the laser diode to pass through the narrow band pass filter.

### Supplementary Note 10

A laser diode driving method including:
applying a pulse-modulated bias to a laser diode to bring the laser diode in pulse oscillation;
applying a reverse bias to the laser diode to make a gain of the laser diode temporarily negative during the pulse oscillation; and
synchronizing the pulse-modulated bias and the reverse bias.

### Supplementary Note 11

The laser diode driving method according to Supplementary Note 10, further including generating a sinusoidal bias for generation of the reverse bias.

Some or all of the elements (e.g., configurations and functions) described in Supplementary Notes 2 to 9 dependent on Supplementary Note 1 {e.g., laser diode driving circuit} may also depend on Supplementary Note 10 {e.g., method} by the same dependency relationship as Supplementary Notes 2 to 9. Some or all of the elements described in any Supplementary Note may be applied to various types of hardware, software, recording means for recording software, systems, and methods.

What is claimed is:

1. A laser diode driving circuit comprising:
a pulse-modulated bias applying circuit configured to apply a pulse-modulated bias to a laser diode to bring the laser diode in pulse oscillation;
a reverse bias current applying circuit configured to apply a reverse bias to the laser diode to make a gain of the laser diode temporarily negative during the pulse oscillation; and
a clock source configured to synchronize the pulse-modulated bias and the reverse bias.

2. The laser diode driving circuit according to claim 1, further comprising a sinusoidal generation circuit configured to generate a sinusoidal bias for generation of the reverse bias.

3. The laser diode driving circuit according to claim 2, further comprising a direct-current bias generation circuit configured to generate a direct-current bias to be applied for adjustment of the sinusoidal bias.

4. The laser diode driving circuit according to claim 3, wherein a positive amplitude of the sinusoidal bias is equal to or more than 50% of an oscillation threshold of the laser diode in only sinusoidal modulation.

5. The laser diode driving circuit according to claim 2, further comprising a merger configured to merge the pulse-modulated bias and the sinusoidal bias, the merger being configured to make a degree of coupling of the pulse-modulated bias and a degree of coupling of the sinusoidal bias different from each other.

6. The laser diode driving circuit according to claim 5, wherein the merger includes a directional coupler or a resistive coupler.

7. The laser diode driving circuit according to claim 2, further comprising a frequency selective filter configured to merge the pulse-modulated bias and the sinusoidal bias, the frequency selective filter being configured to select the sinusoidal bias as a fundamental wave and select the pulse-modulated bias as a harmonic.

8. The laser diode driving circuit according to claim 2, further comprising a phase adjustment circuit configured to control a phase relationship between the pulse-modulated bias and the sinusoidal bias.

9. The laser diode driving circuit according to claim 2, further comprising a narrow band pass filter configured to narrow a pulse waveform, the narrow band pass filter being configured to allow an output from the laser diode to pass through the narrow band pass filter.

10. A laser diode driving method comprising:
applying a pulse-modulated bias to a laser diode to bring the laser diode in pulse oscillation;
applying a reverse bias to the laser diode to make a gain of the laser diode temporarily negative during the pulse oscillation; and
synchronizing the pulse-modulated bias and the reverse bias.

11. The laser diode driving method according to claim 10, further comprising generating a sinusoidal bias for generation of the reverse bias.

12. The laser diode driving method according to claim 11, further comprising generating a direct-current bias to be applied for adjustment of the sinusoidal bias.

13. The laser diode driving method according to claim 12, wherein a positive amplitude of the sinusoidal bias is equal to or more than 50% of an oscillation threshold of the laser diode in only sinusoidal modulation.

14. The laser diode driving method according to claim 11, further comprising merging the pulse-modulated bias and the sinusoidal bias by a merger and making a degree of coupling of the pulse-modulated bias and a degree of coupling of the sinusoidal bias different from each other by the merger.

15. The laser diode driving method according to claim 14, wherein the merger includes a directional coupler or a resistive coupler.

16. The laser diode driving method according to claim 11, further comprising merging the pulse-modulated bias and the sinusoidal bias by a frequency selective filter and selecting the sinusoidal bias as a fundamental wave and the pulse-modulated bias as a harmonic by the frequency selective filter.

17. The laser diode driving method according to claim 11, further comprising controlling a phase relationship between the pulse-modulated bias and the sinusoidal bias by a phase adjustment circuit.

18. The laser diode driving method according to claim 11, further comprising causing an output from the laser diode to pass through a narrow band pass filter configured to narrow a pulse waveform.
